(19) United States
(12) Patent Application Publication
(10) Pub. No.: US 2025/0153037 A1
(43) Pub. Date: May 15, 2025

(54) OPTICAL JOYSTICK APPARATUS

(71) Applicant: I- STAR ELECTRONICS CO, LTD., Shenzhen (CN)

(72) Inventor: Xing Tu, Shenzhen (CN)

(21) Appl. No.: 18/419,203

(22) Filed: Jan. 22, 2024

(30) Foreign Application Priority Data
Nov. 15, 2023 (CN) 2023115201784

(51) Int. Cl. A63F 13/24; H05K 1/02

(52) U.S. Cl. CPC A63F 13/24; H05K 1/0274; H05K 2201/10121; H05K 2201/10151

(57) ABSTRACT

The present invention discloses an optical joystick apparatus including a housing and a joystick. A PCB board is provided in the housing. A light-emitting element and a photosensitive element are provided on the PCB board. The joystick is rotatably connected to the housing. A lower part of the joystick extends into the housing and is provided with a light-shielding portion. The light-emitting element and the photosensitive element are arranged on two sides of the light-shielding portion, respectively.

### TECHNICAL FIELD

The present invention relates to a game control apparatus, and in particular to an optical joystick apparatus.

### BACKGROUND

The Chinese patent application for invention announcement No. CN 116382415 A and entitled “JOYSTICK MODULE” discloses a joystick module, including: a casing, a movable component/reflective component/signal generator, a circuit board, a base, a swing arm, a joystick, a sensor, and another accessory, where the “swing arm” is driven by the “joystick”, then the “movable component/reflective component/signal generator” moves along with the “swing arm”, and then a corresponding signal sensor receives the movement signal. Such a structure has many accessories with a complex transmission relationship. In addition, the accessories (especially a swing arm mechanism) also have very complex structural design, take up a lot of space, and are inconvenient to assemble, causing high production costs. Therefore, developing a new type of optical joystick has become an urgent problem for those skilled in the art to solve.

### SUMMARY

In order to solve the above-mentioned disadvantages, the present invention provides an optical joystick apparatus.

The above-mentioned objective of the present invention is achieved by means of the following technical solution: an optical joystick apparatus, including a housing and a joystick, where a PCB board is provided in the housing, and a light-emitting element and a photosensitive element are provided on the PCB board, where the joystick is rotatably connected to the housing, a lower part of the joystick extends into the housing and is provided with a light-shielding portion, and the light-emitting element and the photosensitive element are arranged on two sides of the light-shielding portion, respectively.

Further, the joystick is provided with a spherical component, and the housing is provided with a spherical slotted hole that matches the spherical component, making the swing of the joystick more stable.

Further, the housing includes a top housing and a bottom housing, and the spherical slotted hole is provided in the top housing.

Further, the top housing and the bottom housing are connected through a snap-fitting structure or screws.

Further, a return spring is sleeved on the joystick on the upper side of the light-shielding portion, and the return spring has an upper end pressing against or fixed to an inner surface of the top of the housing, and a lower end pressing against or fixed to an upper end of the light-shielding portion.

Further, the housing is provided with a limiting structure that limits a swing range of the joystick.

Further, the limiting structure is formed by the upward extension of the spherical slotted hole, or by a protruding rim extending upward from the top of the housing, without the need for an additional limiting component.

Further, the spherical component and the joystick may use a split connection structure or an integrally formed structure. When the split connection structure is used, the joystick is provided with a limiting protrusion that limits a downward movement of the joystick.

Further, there are two pairs, four pairs, or eight pairs of light-emitting elements and photosensitive elements.

Further, the light-shielding portion and the joystick may use a split connection structure or an integrally formed structure. When the split connection structure is used, an interference fit, a thread fit, or a snap fit may be used.

Advantages of the present invention compared with the prior art are as follows: The joystick in the present invention is rotatably connected to the housing, and an integrally formed or split-connected light-shielding portion is directly provided at a lower part of the joystick and directly cooperates with the optical elements on the PCB board for sensing. The present invention obviates the need for a swing arm mechanism of an existing joystick apparatus, and a large number of intermediate transmission mechanisms. The present invention has fewer accessories, which allows for not only easier assembly and lower production costs, but also durability and a long service life.

### BRIEF DESCRIPTION OF THE DRAWINGS

FIG. 1 is a schematic structural diagram of an embodiment 1 of the present invention;

FIG. 2 is a longitudinal sectional view of FIG. 1;

FIG. 3 is a schematic diagram of an independent packaging structure used by the embodiment 1 of the present invention;

FIG. 4 is a schematic diagram of an internal structure of FIG. 3;

FIG. 5 is a schematic structural diagram illustrating that the independently packaged embodiment 1 is installed into a gamepad;

FIG. 6 is a schematic structural diagram illustrating that the embodiment 1 of the present invention is directly assembled into a gamepad;

FIG. 7 is a schematic structural diagram of a light-shielding portion in the shape of a vertical cover in the present invention;

FIG. 8 is a schematic structural diagram of a claw-like light-shielding portion in the present invention;

FIG. 9 is a schematic structural diagram of an embodiment 2 of the present invention;

FIG. 10 is a schematic structural diagram of an embodiment 3 of the present invention;

FIG. 11 is a longitudinal sectional view of FIG. 10;

FIG. 12 is a schematic diagram of an independent packaging structure used by the embodiment 3 of the present invention;

FIG. 13 is a schematic diagram of an internal structure of FIG. 12;

FIG. 14 is a schematic structural diagram illustrating that the independently packaged embodiment 3 is installed into a gamepad;

FIG. 15 is a schematic structural diagram illustrating that the embodiment 3 of the present invention is directly assembled into a gamepad;

FIG. 16 is a schematic structural diagram of an embodiment 4 of the present invention;

FIG. 17 is a schematic structural diagram of an embodiment 5 of the present invention;

FIG. 18 is a schematic diagram of a split structure of a cover-shaped light-shielding portion and a joystick in the present invention;

FIG. 19 is a schematic diagram of a split structure of a flat-shaped light-shielding portion and a joystick in the present invention;

FIG. 20 is a schematic diagram of another limiting structure for limiting a swing range of a joystick in the present invention; and

FIG. 21 is a longitudinal sectional view of FIG. 20.

### DETAILED DESCRIPTION OF EMBODIMENTS

The present invention is further described below in detail with reference to the accompanying drawings.

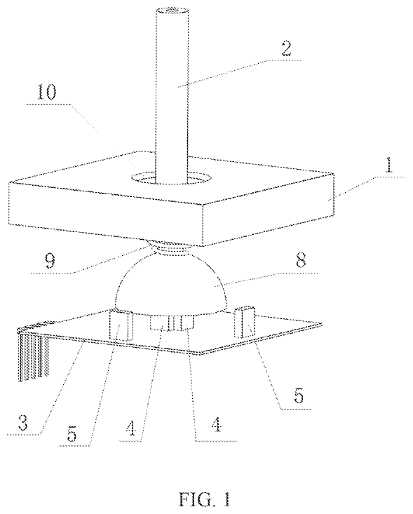

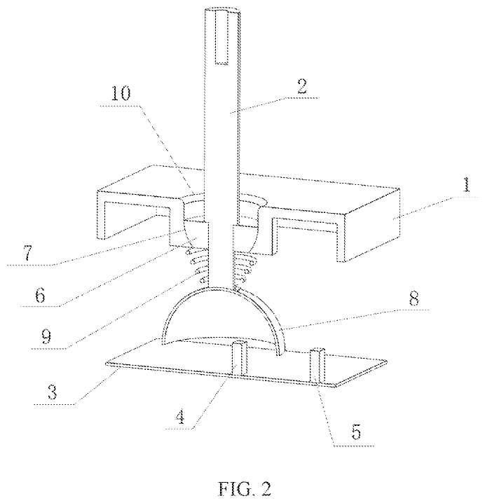

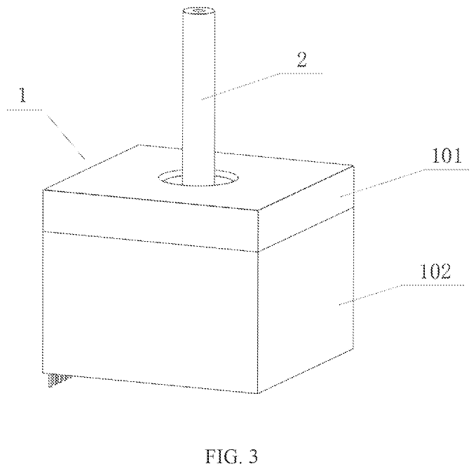

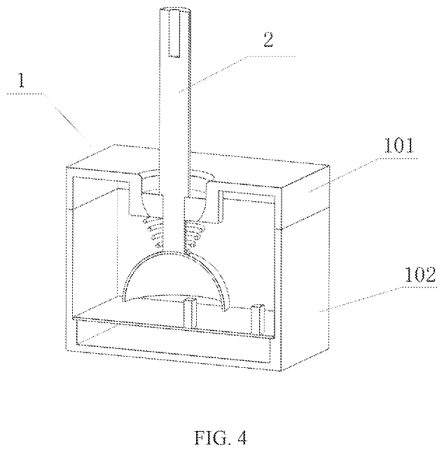

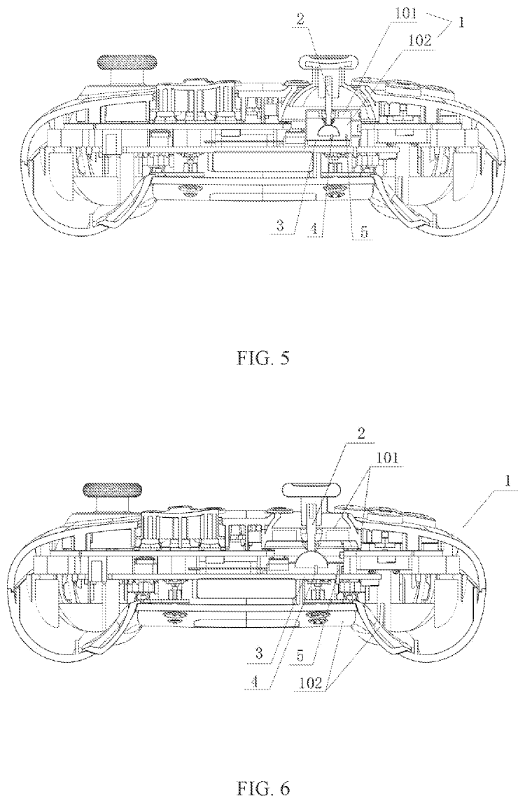

Embodiment 1: As shown in FIGS. 1 and 2, an optical joystick apparatus includes a housing 1 and a joystick 2. The housing 1 may be a housing 1 of an independently packaged optical joystick apparatus (as shown in FIGS. 3 and 4). An assembly structure with the independently packaged present invention installed into a gamepad is as shown in FIG. 5. The housing 1 may also be a housing 1 of a gamepad (as shown in FIG. 6). The housing 1 includes a top housing 101 and a bottom housing 102. The top housing 101 and the bottom housing 102 are connected through a snap-fitting structure or screws.

A PCB board 3 is provided in the bottom housing 102. Two pairs of “light-emitting elements 4 and photosensitive elements 5” are provided on the PCB board 3. The two pairs of “light-emitting elements 4 and photosensitive elements 5” are distributed on the PCB board 3 along two radial lines of the joystick 2 with an included angle of 90 degrees, respectively, and a light path of each pair of the light-emitting element 4 and the photosensitive element 5 coincides with the radial line of the joystick 2.

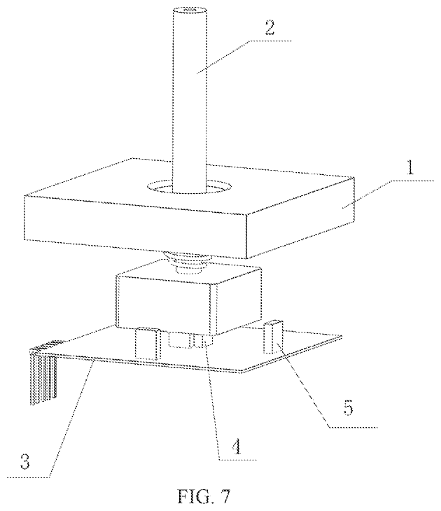

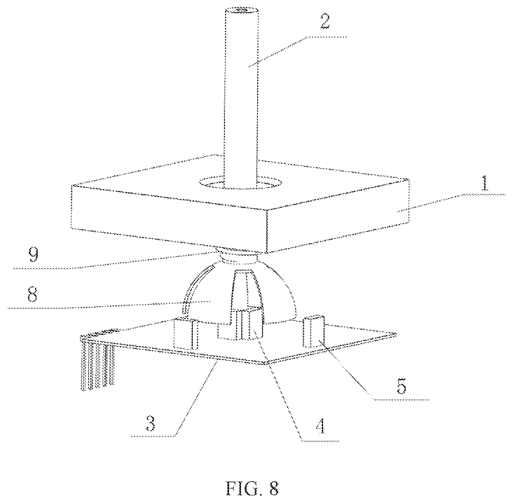

The joystick 2 is rotatably connected to the top housing 101. The joystick 2 is provided with a spherical component 6 integrally formed with the joystick 2, and the top of the top housing 101 is provided with a spherical slotted hole 7 that matches the spherical component 6. The joystick 2 passes through the spherical component 6, and the spherical component 6 is embedded in the spherical slotted hole 7, such that the joystick 2 swings more stably under the restriction of a spherical surface. A lower part of the joystick 2 extends into the bottom housing 102, and extends to form a light-shielding portion 8 that matches the two pairs of “light-emitting elements 4 and photosensitive elements 5”. The light-shielding portion 8 is in the shape of a cover, which may be a curved cover (as in FIG. 1), or may be a vertical cover (as in FIG. 7), or may be a claw-like light-shielding portion with unnecessary parts of the cover removed (as in FIG. 8). The light-shielding portion 8 is integrally formed with the joystick 2. The light-emitting element 4 and the photosensitive element 5 are arranged on two sides of the light-shielding portion 8, respectively.

In order to enable the joystick 2 to automatically return to the original position, a return spring 9 is sleeved on the joystick 2 on the upper side of the light-shielding portion 8. The return spring 9 has an upper end pressing against or fixedly connected to an inner surface of the top housing 101, and a lower end pressing against or fixedly connected to an upper end of the light-shielding portion 8. After swinging, the joystick 2 can quickly return to the original position under the action of the return spring 9.

In order to prevent movement interference between the light-shielding portion 8 and the PCB board 3, the light-emitting element 4, and the photosensitive element 5 from affecting the service life, the top housing 101 is provided with a limiting structure 10 that limits a swing range of the joystick 2. This limiting structure 10 is formed by the upward extension of the spherical slotted hole 7, obviating the need for an additional independent limiting component.

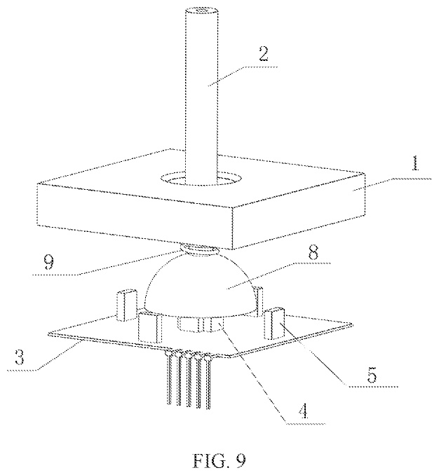

Embodiment 2: As shown in FIG. 9, on the basis of Embodiment 1, the number of “light-emitting elements 4 and photosensitive elements 5” is increased to four pairs. The remaining structures are exactly the same as those in Embodiment 1. By analogy, on the basis of Embodiment 1, the number of “light-emitting elements 4 and photosensitive elements 5” is increased to eight pairs.

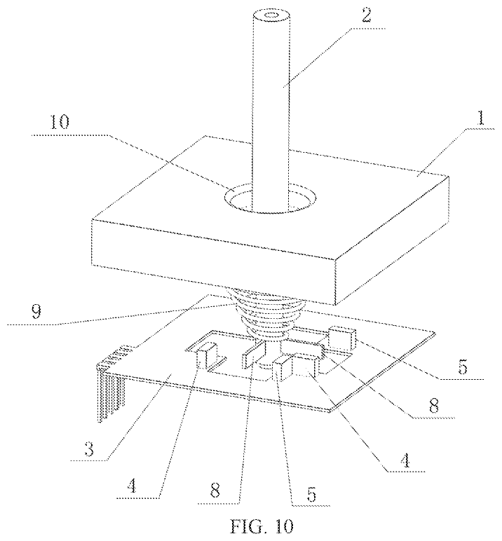

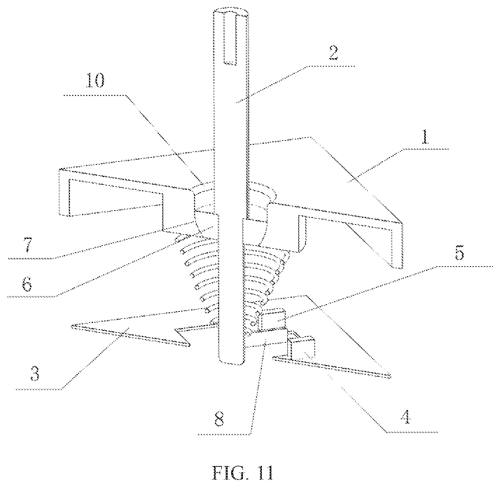

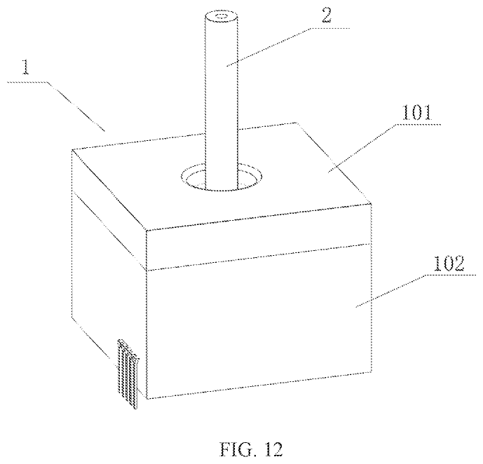

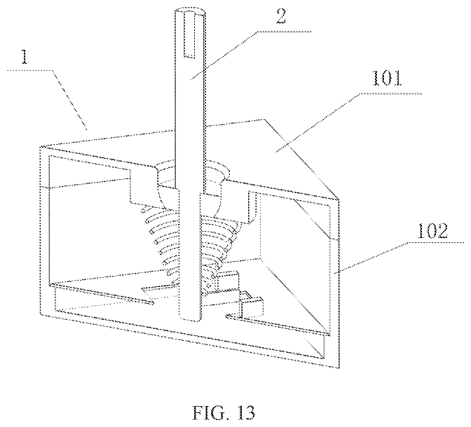

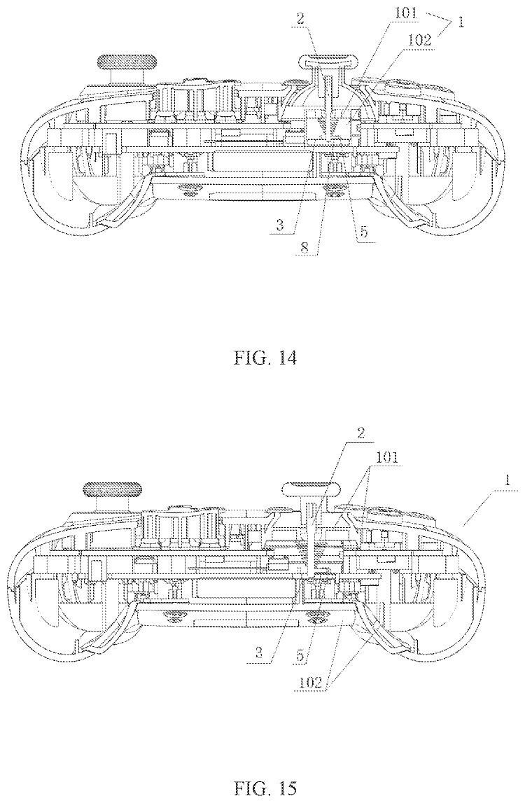

Embodiment 3: As shown in FIGS. 10 and 11, an optical joystick apparatus includes a housing 1 and a joystick 2. The housing 1 may be a housing 1 of an independently packaged optical joystick apparatus (as shown in FIGS. 12 and 13). An assembly structure with the independently packaged present invention installed into a gamepad is as shown in FIG. 14. The housing may also be a housing 1 of a gamepad (as shown in FIG. 15). The housing 1 includes a top housing 101 and a bottom housing 102. The top housing 101 and the bottom housing 102 are connected through a snap-fitting structure or screws.

A PCB board 3 is provided in the bottom housing 102. Two pairs of “light-emitting elements 4 and photosensitive elements 5” are provided on the PCB board 3. The two pairs of “light-emitting elements 4 and photosensitive elements 5” are distributed on the PCB board 3 along two radial lines of the joystick 2 with an included angle of 90 degrees, respectively, and a light path of each pair of the light-emitting element 4 and the photosensitive element 5 is perpendicular to the radial line of the joystick 2.

The joystick 2 is rotatably connected to the top housing 101. The joystick 2 is provided with a spherical component 6 integrally formed with the joystick 2, and the top of the top housing 101 is provided with a spherical slotted hole 7 that matches the spherical component 6. The joystick 2 passes through the spherical component 6, and the spherical component 6 is embedded in the spherical slotted hole 7, such that the joystick 2 swings more stably under the restriction of a spherical surface. A lower part of the joystick 2 extends into the bottom housing 102, and extends to form a light-shielding portion 8 that matches the two pairs of “light-emitting elements 4 and photosensitive elements 5”. The light-shielding portion 8 is flat-shaped. The light-shielding portion 8 is integrally formed with the joystick 2. The light-emitting element 4 and the photosensitive element 5 are arranged on two sides of the light-shielding portion 8, respectively.

In order to enable the joystick 2 to automatically return to the original position, a return spring 9 is sleeved on the joystick 2 on the upper side of the light-shielding portion 8. The return spring 9 has an upper end fixedly connected to an inner surface of the top housing 101, and a lower end fixedly connected to an upper end of the light-shielding portion 8. After swinging, the joystick 2 can quickly return to the original position under the action of the return spring 9.

In order to prevent movement interference between the light-shielding portion 8 and the PCB board 3, the light-emitting element 4, and the photosensitive element 5 from affecting the service life, the top housing 101 is provided with a limiting structure 10 that limits a swing range of the joystick 2. This limiting structure 10 is formed by the upward extension of the spherical slotted hole 7, obviating the need for an additional independent limiting component.

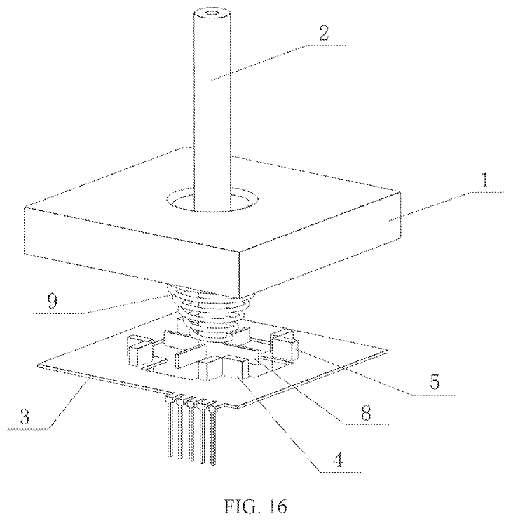

Embodiment 4: As shown in FIG. 16, on the basis of Embodiment 3, the number of “light-emitting elements 4 and photosensitive elements 5” is increased to four pairs, and accordingly the number of light-shielding portions 8 is also increased to four. The remaining structures are exactly the same as those in Embodiment 3. By analogy, on the basis of Embodiment 3, the number of “light-emitting elements 4 and photosensitive elements 5” may also be increased to eight pairs.

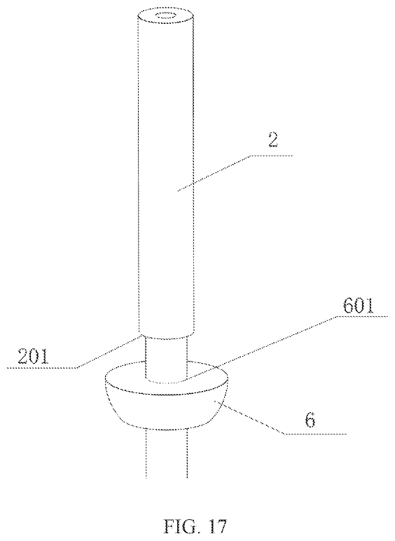

Embodiment 5: As shown in FIG. 17, on the basis of any one of Embodiments 1 to 4, the joystick 2 and the spherical component 6 are provided as a split connection structure. The spherical component 6 is provided with a joystick through hole 601. The joystick 2 is provided with a limiting protrusion 201 that limits a downward movement of the joystick 2.

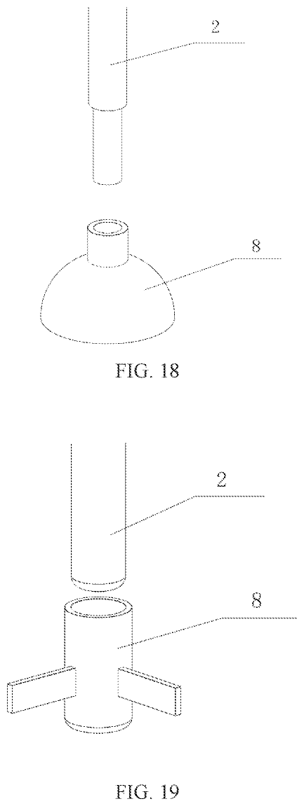

Embodiment 6: As shown in FIGS. 18 and 19, on the basis of any one of Embodiments 1 to 5, the light-shielding portion 8 and the joystick 2 are provided as a split connection structure that uses an interference fit or a thread fit or a snap fit.

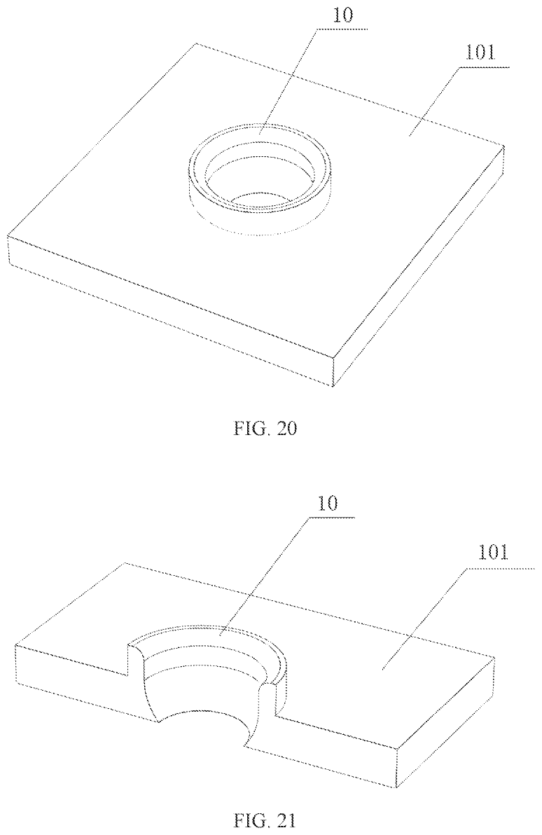

Embodiment 7: As shown in FIGS. 20 and 21, on the basis of any one of Embodiments 1 to 6, the limiting structure 10 provided on the top housing 101 for limiting the swing range of the joystick 2 may also be formed by a protruding rim extending upward from the top of the housing 1, and may be integrally formed with the top housing 101 of the housing 1, also obviating the need for an additional independent limiting component.

The working principle of the present invention is as follows: When swinging, the joystick 2 can directly drive the light-shielding portion 8 at its lower part to move without the aid of any intermediate transmission mechanism, thereby blocking light between the light-emitting element 4 and the photosensitive element 5. Different amounts of light are blocked depending on swing angles of the joystick. Therefore, an amount of light received by the photosensitive element 5 changes, and then different resistance values are generated and delivered to a single-chip microcomputer on a main board. The single-chip microcomputer analyzes and determines a swing angle/orientation or the like of the joystick based on the resistance values generated by the photosensitive component at two angles.

The foregoing description is merely illustrative of the embodiments of the present invention, and is not intended to limit the patent scope of the present invention. Any transformations of equivalent structures or equivalent procedures made using the contents of the specification and the accompanying drawings of the present invention, or any direct or indirect applications thereof in other related technical fields shall equally fall within the scope of patent protection of the present invention.

What is claimed is:

1. An optical joystick apparatus, comprising a housing and a joystick, wherein a PCB board is provided in the housing, and a light-emitting element and a photosensitive element are provided on the PCB board, wherein the joystick is rotatably connected to the housing, a lower part of the joystick extends into the housing and is provided with a light-shielding portion, and the light-emitting element and the photosensitive element are arranged on two sides of the light-shielding portion, respectively.

2. The optical joystick apparatus according to claim 1, wherein the joystick is provided with a spherical component, and the housing is provided with a spherical slotted hole that matches the spherical component.

3. The optical joystick apparatus according to claim 2, wherein the housing comprises a top housing and a bottom housing, and the spherical slotted hole is provided in the top housing.

4. The optical joystick apparatus according to claim 3, wherein the top housing and the bottom housing are connected through a snap-fitting structure or screws.

5. The optical joystick apparatus according to claim 1, wherein a return spring is sleeved on the joystick on the upper side of the light-shielding portion, and the return spring has an upper end pressing against or fixed to an inner surface of the top of the housing, and a lower end pressing against or fixed to an upper end of the light-shielding portion.

6. The optical joystick apparatus according to claim 1, wherein the housing is provided with a limiting structure that limits a swing range of the joystick.

7. The optical joystick apparatus according to claim 6, wherein the limiting structure is formed by the upward extension of the spherical slotted hole, or by a protruding rim extending upward from the top of the housing.

8. The optical joystick apparatus according to claim 2, wherein the spherical component and the joystick use a split connection structure or an integrally formed structure; and when the split connection structure is used, the joystick is provided with a limiting protrusion that limits a downward movement of the joystick.

9. The optical joystick apparatus according to claim 1, wherein there are two pairs, four pairs, or eight pairs of light-emitting elements and photosensitive elements.

10. The optical joystick apparatus according to claim 1, wherein the light-shielding portion and the joystick use a split connection structure with an interference fit, or a split connection structure with a thread fit, or a split connection structure with a snap fit, or an integrally formed structure.
